(19) United States
(12) Patent Application Publication
(10) Pub. No.: US 2020/0120805 A1
(43) Pub. Date: Apr. 16, 2020

(54) EMBEDDED CIRCUIT BOARD AND METHOD OF MAKING SAME

(71) Applicants: QING DING PRECISION ELECTRONICS (HUAIAN) CO.,LTD, Huai an (CN); Avary Holding (Shenzhen) Co., Limited., Shenzhen (CN)

(72) Inventors: BIAO LI, Shenzhen (CN); HAO-WEN ZHONG, Shenzhen (CN)

(21) Appl. No.: 16/662,241

(22) Filed: Oct. 24, 2019

Related U.S. Application Data
(63) Continuation-in-part of application No. PCT/CN2018/110153, filed on Oct. 12, 2018.

(51) Int. Cl. H05K 1/18; H05K 3/00; H05K 3/32; H05K 3/42; H05K 3/46

(52) U.S. Cl. CPC H05K 1/186; H05K 1/189; H05K 3/0017; H05K 3/32; H05K 3/4644; H05K 3/429; H05K 3/4602; H05K 3/4611; H05K 3/424

(57) ABSTRACT

The present invention provides a method of fabricating an embedded circuit board, including: providing an inner laminated structure (10) which is a double-sided circuit board; providing a third circuit board (103) and a fourth circuit board (104), and respectively laminating them on two sides of the inner laminated structure (10); two spaced through holes (30) are formed in the structure obtained in the previous step; electroplating an outer surface of the third circuit board (103) and the fourth circuit board (104) and an inner surface of the through holes (30) to form a first plating layer (50); removing a structure between the two through holes (30) to form a slot (40) having the two through holes (30) at two ends; the electronic component (200) is received and fixed in a middle portion of the slot (40) such that electrodes (201) of the electronic component (200) are directed to the two ends of the slot (40) and electrically connect to the first plating layer (50); providing a first circuit board (101) and a second circuit board (102), respectively laminating them on two sides of the structure obtained in the previous step to embed the electronic component (200); performing surface treatment on the structure obtained in the previous step to obtain an embedded circuit board (100). The present invention also provides an embedded circuit board (100) fabricated by the above manufacturing method.

### FIELD

The invention relates to a circuit board and a manufacturing method thereof, in particular to an embedded circuit board and a manufacturing method thereof.

### BACKGROUND

In recent years, electronic products have been widely used in daily work and life, and light, thin, and small electronic products are becoming more and more popular. Being the main component of electronic products, flexible circuit boards occupy a large space in electronic products. Therefore, the volume of flexible circuit boards greatly affects the volume of electronic products. Large-volume flexible circuit boards are difficult to comply with the trend of thin, short, and small electronic products.

The existing embedded circuit board is most commonly embedded by the method of component mounting and reflow soldering. That is, the solder paste is printed on the pad after the substrate circuit is fabricated, and the component is attached to the surface of the solder paste. The 1R furnace is flow-welded and solidified, and then the components are embedded by lamination and pressing. The components of the embedded circuit board fabricated by the embedding process are fixed on one substrate by surface mounting technology. This connection method cannot provide Anylayer conductivity of the circuit board, and the solder paste on the bottom of the component is soldered. The solder paste occupies a certain thickness (about 40 urn), which is not conducive to thinning of the circuit board.

### CONTENTS OF INVENTION

In view of the above, it is necessary to provide a method for fabricating an embedded circuit board having the above problems, and to provide an embedded circuit board produced by the above manufacturing method.

A method of manufacturing an embedded circuit board, comprising the steps of:

Providing an inner laminate structure, the inner laminate structure being a double-sided circuit board;

Providing a third circuit board and a fourth circuit board, and pressing the third circuit board and the fourth circuit board to two sides of the inner laminated structure respectively;

Opening two spaced through holes in the structure obtained in the previous step;

Electroplating the outer side surfaces of the third circuit board and the fourth circuit board and the inner side of the through holes to form a first plating layer;

Removing the structure between the two through holes to form a slot having the two through holes as both ends;

The electronic component is received and fixed in the middle portion of the slot such that the electrodes of the electronic component are respectively directed to both ends of the slot and electrically connected to the fust plating layer;

Providing a first circuit board and a second circuit board, and pressing the first circuit board and the second circuit board respectively to both sides of the structure obtained in the previous step to embed the electronic component;

The structure obtained in the previous step is subjected to surface treatment to obtain the embedded circuit board.

An embedded circuit board comprising at least an inner laminated structure, a first circuit board, a second circuit board, a third circuit board, a fourth circuit board, a first plating layer, and a second plating layer; the third circuit board and the fourth circuit board are respectively disposed on two sides of the inner laminated structure, the embedded circuit board further includes a slot, the slot penetrates the third circuit board, the inner laminated structure, and the fourth circuit board; the electronic component is received and fixed in the slot, and the electrodes of the electronic component are respectively directed to the inner side of two ends of the slot; the first plating layer is disposed on an outer surface of the third circuit board and the fourth circuit board, and a portion of an inner surface of the slot to electrically connect the third circuit board, the fourth circuit board, the inner laminated structure, and the electrodes of the electronic component; the first circuit board and the second circuit board are respectively disposed on an outer side of the first plating layer, and cover an opening of the slot to embed the electronic component; the second plating layer is disposed on an outer surface of the first circuit board and the second circuit board, and the first circuit board and the second circuit board are electrically connected to the first plating layer.

Compared with the prior art, the method for fabricating the embedded circuit board of the present invention is to embed the electronic component by designing the slot through which the sidewalls of both ends are conductive, using the first plating layer disposed on the inner surface of the slot and the outer surface of the third circuit board and the fourth circuit board, and the second plating layer disposed on the outer side of the first circuit board and the second circuit board, to realize electrical conduction between the electronic component and each circuit board layer, thereby realizing an Anylayer design of the embedded circuit board to be able to use any circuit board layer to externally electrically connect.

In addition, the method for fabricating the embedded circuit board of the present invention avoids printing the conductive paste on a bottom of the electronic component, thereby eliminating a thickness (about 40 um) that the conductive paste may occupy, and improving a slimming effect of the embedded circuit board.

### BRIEF DESCRIPTION OF THE DRAWINGS

FIG. 1 is a flow chart showing the fabrication of an embedded circuit board in accordance with a preferred embodiment of the present invention.

FIG. 2A is a schematic cross-sectional view of an inner laminated structure applied to the fabrication method shown in FIG. 1.

FIG. 2B is a schematic cross-sectional view of the inner laminated structure in another embodiment.

FIG. 3 is a cross-sectional view showing the third circuit board and the fourth circuit board respectively pressed to the sides of the inner laminated structure shown in FIG. 2A.

FIG. 4 is a cross-sectional view showing the structure after opening two through holes in the structure shown in FIG. 3.

FIG. 5 is a cross-sectional view showing the structure shown in FIG. 4 after plating.

FIG. 6A and FIG. 6B are respectively a schematic cross-sectional view and a top plan view of the structure shown in FIG. 5 after forming a slot.

FIG. 7 is a schematic cross-sectional view showing the electronic component fixed to the slot.

FIG. 8 is a cross-sectional view showing the first circuit board and the second circuit board pressed to the structure shown in FIG. 7.

FIG. 9 is a cross-sectional view showing the obtained embedded circuit board in accordance with the manufacturing method shown in FIG. 1.

### DESCRIPTION OF MAIN ELEMENTS AND ELEMENT NUMBERS

| | |
|---|---|
| Embedded circuit board | 100 |
| First circuit board | 101 |
| Second circuit board | 102 |
| Third circuit board | 103 |
| Fourth circuit board | 104 |
| Fifth circuit board | 105 |
| Sixth circuit board | 106 |
| Seventh circuit board | 107 |
| Eighth circuit board | 108 |
| Electronic component | 200 |
| Electrode | 201 |
| Inner laminated structure | 10 |
| Flexible copper clad laminate | 11 |
| Copper foil layer | 12 |
| Adhering layer | 13 |
| Base film | 14 |
| Electrical conductor | 15 |
| Filling hole | 16 |
| First adhesive layer | 20 |
| Through hole | 30 |
| Slot | 40 |
| First plating layer | 50 |
| Conductive paste | 60 |
| Second adhesive layer | 70 |
| Via | 80 |
| Second plating layer | 90 |
| Conductive structure | 91 |

The invention will be further illustrated by the following detailed description in conjunction with the accompanying drawings.

### DETAILED DESCRIPTION

The technical solutions in the embodiments of the present invention are clearly and completely described in the following with reference to the accompanying drawings in the embodiments of the present invention. It is obvious that the described embodiments are only a part of the embodiments of the present invention, and not all embodiments. All other embodiments obtained by those skilled in the art based on the embodiments of the present invention without creative efforts are within the scope of the present invention.

All technical and scientific terms used herein have the same meaning as commonly understood by, one of ordinary skill in the art to which this invention belongs, unless otherwise defined. The terminology used in the description of the present invention is for the purpose of describing particular embodiments and is not intended to limit the invention.

Some embodiments of the present invention are described in detail below with reference to the accompanying drawings. The features of the embodiments and examples described below can be combined with each other without conflict.

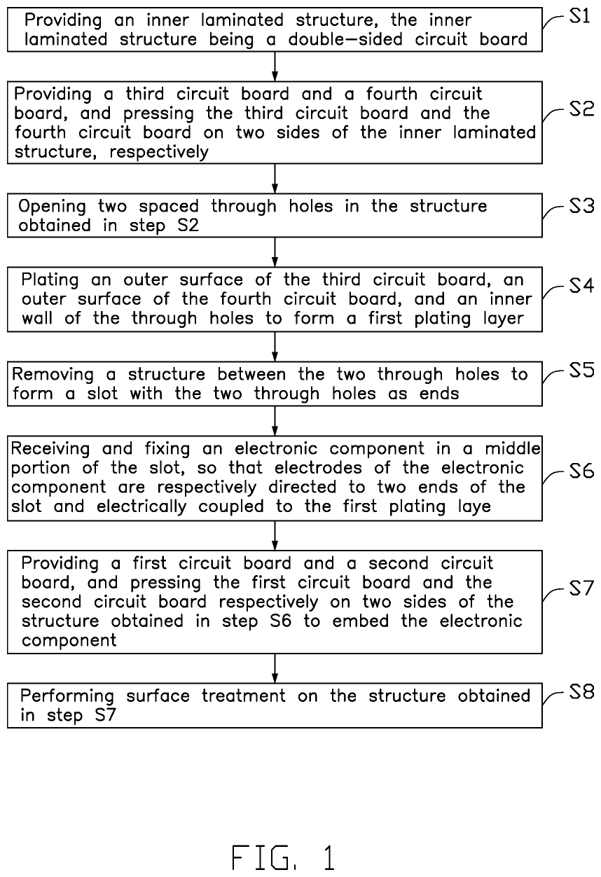

Please refer to FIG. 1, which is a preferred embodiment of a manufacturing method of an embedded circuit board 100. The method includes the following steps:

S1: an inner laminated structure is provided. The inner laminated structure is a double-sided circuit board;

S2: a third circuit board and a fourth circuit board are provided, and the third circuit board and the fourth circuit board are pressed on two sides of the inner laminated structure, respectively;

S3: two spaced through holes are opened in the structure obtained in step S2;

S4: an outer surface of the third circuit board, an outer surface of the fourth circuit board, and an inner wall of the through holes are plated to form a first plating layer;

S5: a structure between the two through holes is removed to form a slot with the two through holes as ends;

S6: an electronic component is received and fixed in a middle portion of the slot, so that electrodes of the electronic component are respectively directed to two ends of the slot and electrically coupled to the first plating layer;

S7: a first circuit board and a second circuit board are provided, and the first circuit board and the second circuit board are respectively pressed on two sides of the structure obtained in step S6 to embed the electronic component;

S8: surface treatment is performed on the structure obtained in step S7.

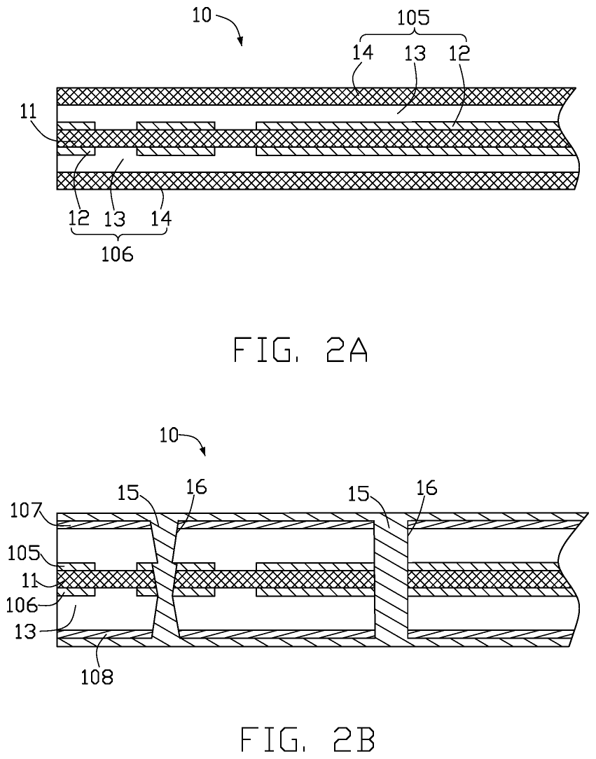

FIGS. 2A-9 show a process of fabricating the embedded circuit board 100. Specifically:

As shown in FIG. 2A, in step S1, the inner laminated structure 10 is provided. The inner laminated structure 10 is a double-sided circuit board. The inner laminated structure 10 can be a flexible printed circuit board (FPC), a rigid-flex board, or a high density interconnect board (HDI).

In one embodiment, the inner laminated structure 10 is a flexible printed circuit board and includes two layers of circuit boards. Specifically, the inner laminated structure 10 includes a flexible copper clad laminate 11, and a fifth circuit board 105 and a sixth circuit board 106 respectively disposed on two sides of the flexible copper clad laminate 11. The flexible copper clad laminate 11 is a double-sided substrate. The fifth circuit board 105 and the sixth circuit board 106 each include a copper foil layer 12, an adhering layer 13 (CVL-AD), and a base film 14 (CVL-PI). The copper foil layer 12 is attached to one side of the base film 14 through the adhering layer 13. The copper foil layer 12 is press-fitted onto the flexible copper clad laminate 11.

It can be understood that, before pressing the copper foil layer 12, the copper foil layer 12 is processed to form a circuit pattern.

In this embodiment, a material of the adhering layer 13 is a resin having viscosity. More specifically, the resin can be selected from at least one of polypropylene, epoxy resin, polyurethane, phenolic resin, urea resin, melamine-formaldehyde resin, and polyimide.

In this embodiment, a material of the base film 14 can be selected from one of, but is not limited to, polyimide (PI), liquid crystal polymer (LCP), polyethylene terephthalate (PET), and polyethylene naphthalate (PEN).

It can be understood that, a number of circuit boards of the inner laminated structure 10 can be designed according to actual needs. In other embodiments, the number of circuit boards of the inner laminated structure 10 can be four, six, eight, . . . or other 2n number of layers.

Please refer to FIG. 2B, in another embodiment, the inner laminated structure 10 is a rigid-flex circuit board which has four layers of circuit boards. Specifically, the inner laminated structure 10 includes the flexible copper clad laminate 11, a fifth circuit board 105 and a sixth circuit board 106 respectively disposed on two sides of the flexible copper clad laminate 11, and a seventh circuit board 107 and an eighth circuit board 108 respectively disposed on an outer surface of the fifth circuit board 105 and the sixth circuit board 106. The seventh circuit board 107 and the eighth circuit board 108 are respectively pressed onto the fifth circuit board 105 and the sixth circuit board 106 by an adhering layer 13. The fifth circuit board 105 and the sixth circuit board 106 are soft boards, and the seventh circuit board 107 and the eighth circuit board 108 are hard boards.

In another embodiment, the inner laminated structure 10 further includes an electrical conductor 15 that effects electrical conduction between various layers of circuit boards. Specifically, each layer of the inner layer 10 is provided with a filling hole 16, and the electrical conductor 15 fills the filling hole 16 to electrically conduct the circuit boards. The filling hole 16 can be a blind hole or a through hole.

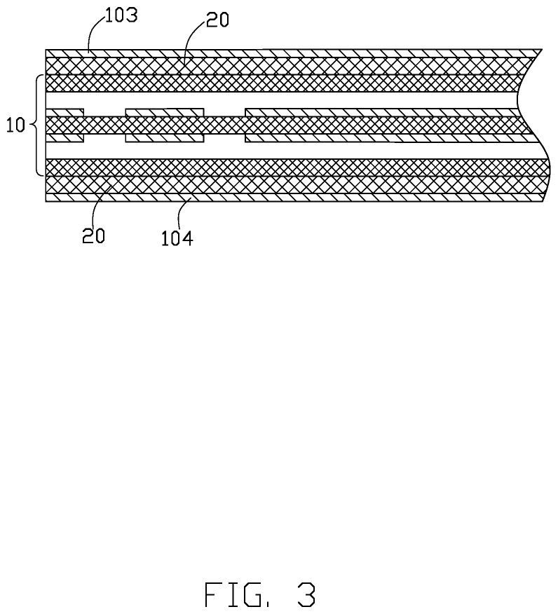

As shown in FIG. 3, in step S2, the third circuit board 103 and the fourth circuit board 104 are provided, and the third circuit board 103 and the fourth circuit board 104 are respectively pressed on two sides of the inner laminated structure 10.

In this embodiment, the third circuit board 103 and the fourth circuit board 104 are high density interconnect boards (HDI boards). The third circuit board 103 and the fourth circuit board 104 are respectively pressed on the two sides of the inner laminated structure 10 through the first adhesive layer 20.

A material of the first adhesive layer 20 is a resin having viscosity. More specifically, the resin can be selected from at least one of polypropylene, epoxy resin, polyurethane, phenolic resin, urea resin, melamine-formaldehyde resin, and polyimide.

It can be understood that, before pressing the third circuit board 103 and the fourth circuit board 104, the third circuit board 103 and the fourth circuit board 104 are processed to form a circuit pattern.

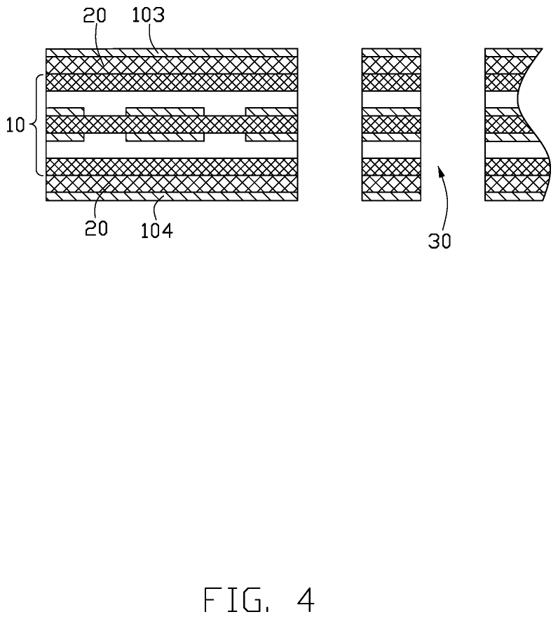

As shown in FIG. 4, in step S3, two spaced through holes 30 are formed. The through holes 30 can be formed by diamond etching or the like. In this embodiment, the through hole 30 is a circular hole.

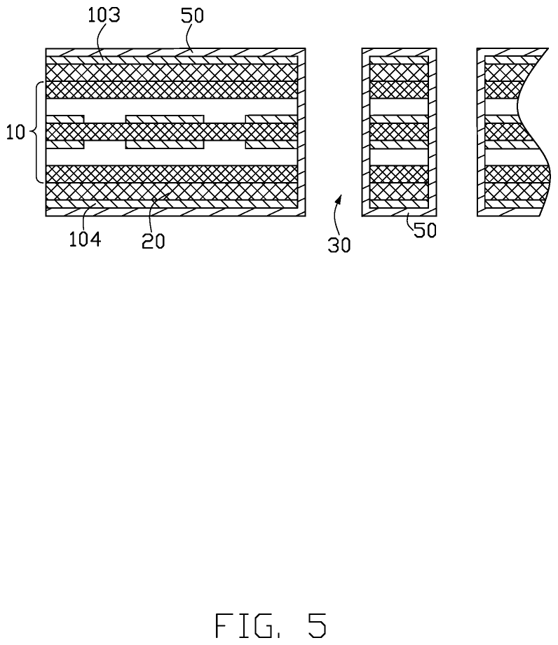

As shown in FIG. 5, in step S4, outer surfaces of the third circuit board 103 and of the fourth circuit board 104 and an inner wall of the two through holes 30 are plated to form a first plating layer 50. The sixth circuit board 106, the fifth circuit board 105, the fourth circuit board 104, and the third circuit board 103 are each electrically connected to the first plating layer 50.

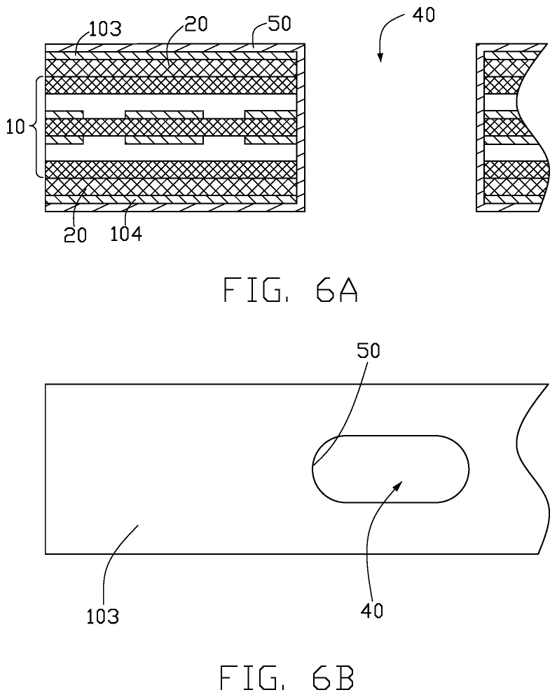

As shown in FIGS. 6a and 6b, in step S5, a structure between the two through holes 30 is removed to form a slot 40 having the two through holes 30 as two ends. Specifically, the structure between the two through holes 30 can be removed by diamond etching or the like. In one embodiment, two ends of the slot 40 are semicircular.

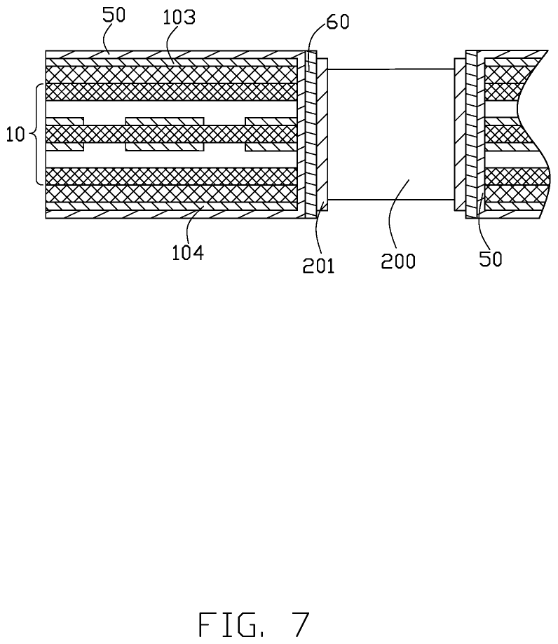

As shown in FIG. 7, in step S6, the electronic component 200 is received and fixed in a middle portion of the slot 40, so that the electrodes 201 of the electronic component 200 are respectively directed to the two ends of the slot 40 and electrically connect to the first plating layer 50.

Specifically, the electronic component 200, such as a capacitor, is placed in the middle portion of the slot 40. A conductive paste 60 is printed between the electronic component 200 and the two ends of the slot 40. Finally, the conductive paste 60 is dried to fix the electronic component 200. The conductive paste 60 electrically connects the electrodes 201 of the electronic component 200 and the first plating layer 50. The conductive paste 60 can be any one of a solder paste, a silver paste, a copper paste, and the like.

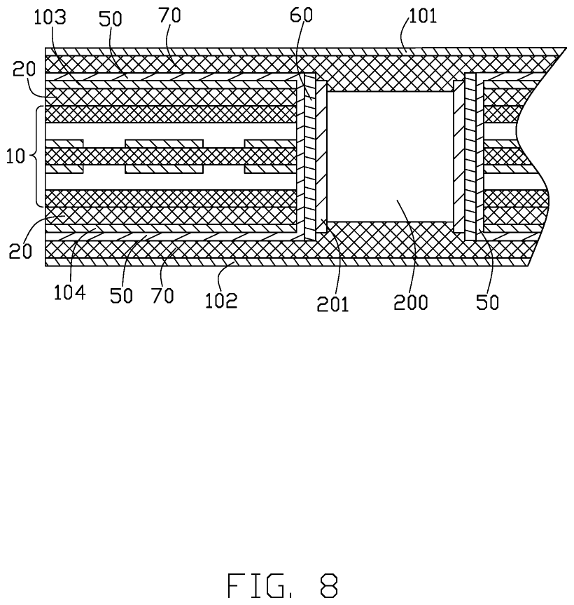

As shown in FIG. 8, in step S7, the first circuit board 101 and the second circuit board 102 are provided, and the first circuit board 101 and the second circuit board 102 are respectively pressed on two sides of the structure formed in step S6 to embed the electronic component 200.

In this embodiment, the first circuit board 101 and the second circuit board 102 are high density interconnect (HDI) boards and are respectively pressed on the first plating layer 50 through the second adhesive layer 70. The first circuit board 101 and the second circuit board 102 respectively cover an opening of the slot 40 from two sides to embed the electronic component 200.

A material of the second adhesive layer 70 is a resin having viscosity. More specifically, the resin can be selected from at least one of polypropylene, epoxy resin, polyurethane, phenolic resin, urea resin, melamine-formaldehyde resin, and polyimide. In this embodiment, the material of the second adhesive layer 70 is the same as the material of the first adhesive layer 20.

It can be understood that, before pressing the first circuit board 101 and the second circuit board 102, the first circuit board 101 and the second circuit board 102 are surface-treated to form a circuit pattern.

It can be understood that, after pressing the first circuit board 101 and the second circuit board 102, a via 80 is formed in the first circuit board 101 and in the second circuit board 102, for assisting in achieving electrical connection between the first circuit board 101 and the second circuit board 102 with the first plating layer 50 in later steps. The via 80 extends through the first circuit board 101, the second circuit board 102, and the second adhesive layer 70.

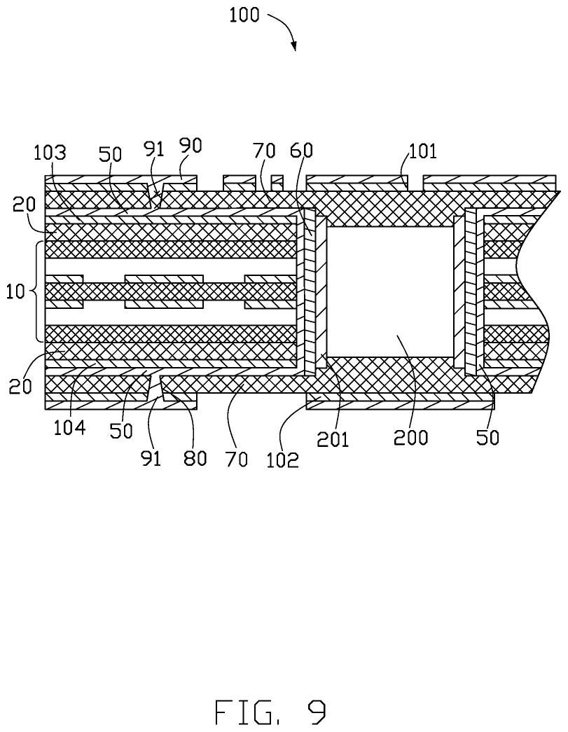

As shown in FIG. 9, in step S8, the structure shown in block S7 is surface treated to obtain the embedded circuit board 100.

Specifically, on an outer surface of the first circuit board 101 and the second circuit board 102, a second plating layer 90 is formed, and electrical conduction between the second plating layer 90 and the first plating layer 50 is simultaneously achieved. Specifically, the via 80 is filled with a conductive material or plated to form a conductive structure 91. The conductive structure 91 electrically connects the first circuit board 101, the second circuit board 102, and the second plating layer 90 to the first plating layer 50.

Please refer again to FIG. 9, a preferred embodiment of this invention further provides an embedded circuit board 100, which at least includes an inner laminated structure 10, a first circuit board 101, a second circuit board 102, a third circuit board 103, a fourth circuit board 104, a first plating layer 50, and a second plating layer 90. The third circuit board 103 and the fourth circuit board 104 are respectively disposed on two sides of the inner laminated structure 10. The embedded circuit board 100 further includes a slot 40. The slot 40 extends through the third circuit board 103, the inner laminated structure 10, and the fourth circuit board 104. An electronic component 200 is received and fixed in the slot 40, and electrodes 201 of the electronic component 200 respectively face the slot 40 toward an inner surface of two ends. The first plating layer 50 is disposed on an outer side of the third circuit board 103 and the fourth circuit board 104, and toward the inner surface of the two ends of the slot 40, to electrically connect the third circuit board 103, the fourth circuit board 104, the inner laminated structure 10, and the electrodes 201 of the electronic component 200. The first circuit board 101 and the second circuit board 102 are each disposed on an outer side of the first plating layer 50 and cover an opening of the slot 40 to embed the electronic component 200. The second plating layer 90 is disposed on an outer side of the first circuit board 101 and the second circuit board 102 and electrically connects the first circuit board 101 and the second circuit board 102 to the first plating layer 50.

The inner laminate 10 is a double-sided circuit board. The inner laminate 10 can be a flexible printed circuit board (FPC), a rigid-flex board, or a high density interconnect board (HDI). In this embodiment, the inner laminated structure 10 is a flexible printed circuit board and includes two layers of circuit boards. Specifically, the inner laminated structure 10 includes a flexible copper clad laminate 11 and a fifth circuit board 105 and a sixth circuit board 106 respectively disposed on two sides of the flexible copper clad laminate 11. The flexible copper clad laminate 11 is a double-sided substrate. The fifth circuit board 105 and the sixth circuit board 106 each include a copper foil layer 12, an adhering layer 13 (CVL-AD), and a base film 14 (CVL-PI). The copper foil layer 12 is attached to one side of the base film 14 through the adhering layer 13. The copper foil layer 12 is press-fitted onto the flexible copper clad laminate 11. The two copper foil layers 12 are each electrically conducted to the first plating layer 50.

In this embodiment, a material of the adhering layer 13 is a resin having viscosity. More specifically, the resin can be selected from at least one of polypropylene, epoxy resin, polyurethane, phenolic resin, urea resin, melamine-formaldehyde resin, and polyimide.

In this embodiment, a material of the base film 14 can be selected from one of, but is not limited to, polyimide (PI), liquid crystal polymer (LCP), polyethylene terephthalate (PET), and polyethylene naphthalate (PEN).

It can be understood that, a number of circuit boards of the inner laminated structure 10 can be designed according to actual needs. In other embodiments, the number of circuit boards of the inner laminated structure 10 can be four, six, eight, . . . or other 2n number of layers.

In another embodiment, as shown in FIG. 2B, the inner laminated structure 10 is a rigid-flex circuit board which has four layers of circuit boards. Specifically, the inner laminated structure 10 includes the flexible copper clad laminate 11, a fifth circuit board 105 and a sixth circuit board 106 respectively disposed on two sides of the flexible copper clad laminate 11, and a seventh circuit board 107 and an eighth circuit board 108 respectively disposed on an outer surface of the fifth circuit board 105 and the sixth circuit board 106. The seventh circuit board 107 and the eighth circuit board 108 are respectively pressed onto the fifth circuit board 105 and the sixth circuit board 106 by an adhering layer 13. The fifth circuit board 105 and the sixth circuit board 106 are soft boards, and the seventh circuit board 107 and the eighth circuit board 108 are hard boards.

In another embodiment, the inner laminated structure 10 further includes an electrical conductor 15 that effects electrical conduction between various layers of circuit boards. Specifically, each layer of the inner layer 10 is provided with a filling hole 16, and the electrical conductor 15 fill; the filling hole 16 to electrically conduct the circuit boards. The filling hole 16 can be a blind hole or a through hole.

Please refer again to FIG. 9, in this embodiment, the third circuit board 103 and the fourth circuit board 104 are high density interconnect (HDI) boards. The third circuit board 103 and the fourth circuit board 104 respectively are pressed on two sides of the inner laminated structure 10 through the first adhesive layer 20.

A material of the first adhesive layer 20 is a resin having viscosity. More specifically, the resin can be selected from at least one of polypropylene, epoxy resin, polyurethane, phenolic resin, urea resin, melamine-formaldehyde resin, and polyimide.

The slot 40 is formed by diamond etching or the like. In the embodiment, the two ends of the slot 40 are semi-circular, and a middle of the slot 40 has a rectangular shape. The electrodes 201 of the electronic component 200 are electrically connected to the first plating layer 50 through a conductive paste 60. The conductive paste 60 may be any one of a solder paste, a silver paste, a copper paste, and the like.

In this embodiment, the first circuit board 101 and the second circuit board 102 are high density interconnect (HDI) boards, and are each pressed on the first plating layer 50 through the second adhesive layer 70. The first circuit board 101 and the second circuit board 102 respectively cover an opening of the slot 40 from two sides to embed the electronic component 200.

A material of the second adhesive layer 70 is a resin having viscosity. More specifically, the resin can be selected from at least one of polypropylene, epoxy resin, polyurethane, phenolic resin, urea resin, melamine-formaldehyde resin, and polyimide. In this embodiment, the material of the second adhesive layer 70 is the same as the material of the first adhesive layer 20.

The first circuit board 101 and the second circuit board 102 further form a via 80. The via 80 extends through the first circuit board 101/the second circuit board 102 and the second adhesive layer 70. The second plating layer 90 further includes a conductive structure 91. The conductive structure 91 fills in the via 80 to electrically couple the first circuit board 101, the second circuit board 102, and the second plating layer 90 to the first plating layer 50.

Compared with the prior art, the method for fabricating the embedded circuit board 100 of the present invention is to embed the electronic component 200 by designing the slot 40 through which the sidewalls of both ends are conductive, using the first plating layer 50 disposed on the inner surface of the slot 40 and the outer surface of the third circuit board 103 and the fourth circuit board 104, and the second plating layer 90 disposed on the outer side of the first circuit board 101 and the second circuit board 102, to realize electrical conduction between the electronic component 200 and each circuit board layer, thereby realizing an Anylayer design of the embedded circuit board 100 to be able to use any circuit board layer to externally electrically connect.

In addition, the method for fabricating the embedded circuit board 100 of the present invention avoids printing the conductive paste 60 on a bottom of the electronic component 200, thereby eliminating a thickness (about 40 um) that the conductive paste 60 may occupy, and improving a slimming effect of the embedded circuit board 100.

The embodiments shown and described above are only examples. Even though numerous characteristics and advantages of the present technology have been set forth in the foregoing description, together with details of the structure and function of the present invention, the invention is illustrative only, and changes may be made in the detail, including in matters of shape, size and arrangement of the parts within the principles of the present invention up to, and including, the full extent established by the broad general meaning of the terms used in the claims.

What is claimed is:

1. A method of manufacturing an embedded circuit board, comprising the steps of:
providing an inner laminated structure, the inner laminated structure being a double-sided circuit board;
providing a third circuit board and a fourth circuit board, and pressing the third circuit board and the fourth circuit board on two sides of the inner laminated structure respectively;
opening two spaced through holes in the structure obtained in the previous step;
electroplating an outer surface of the third circuit board and the fourth circuit board and an inner surface of the through holes to form a first plating layer;
removing a structure between the two through holes to form a slot having the two through holes as two ends;
receiving and fixing an electronic component in a middle portion of the slot such that electrodes of the electronic component are respectively directed to two ends of the slot and electrically connected to the first plating layer;
providing a first circuit board and a second circuit board, and pressing the fust circuit board and the second circuit board respectively on two sides of the structure obtained in the previous step to embed the electronic component; and
performing surface treatment on the structure obtained in the previous step to obtain the embedded circuit board.

2. The method of fabricating an embedded circuit board according to claim 1, wherein the inner laminated structure comprises a flexible copper clad laminate, and a fifth circuit board and a sixth circuit board respectively disposed on two sides of the flexible copper clad laminate; the fifth circuit board and the sixth circuit board are each electrically connected to the first plating layer; the fifth circuit board and the sixth circuit board each comprise a copper foil layer, an adhering layer, and a base film, the copper foil layer being attached to one side of the base film by the adhering layer, and the copper foil layer laminated to the flexible copper clad laminate.

3. The method of fabricating an embedded circuit board according to claim 1, wherein the inner laminated structure comprises a flexible copper clad laminate, a fifth circuit board and a sixth circuit board respectively disposed on two sides of the flexible copper clad laminate, and a seventh circuit board and an eighth circuit board respectively disposed on an outer side of the fifth circuit board and the sixth circuit board; the seventh circuit board and the eighth circuit board are respectively laminated to the fifth circuit board and the sixth circuit board through an adhering layer; the inner laminated structure further comprises an electrical conductor for realizing electrical conduction between the circuit boards of the respective layers, each circuit board layer of the inner laminated structure forms a filling hole; and the electric conductor fills in the filling hole to electrically conduct the respective circuit boards.

4. The method of fabricating an embedded circuit board according to claim 1, wherein the third circuit board and the fourth circuit board are respectively laminated to two sides of the inner laminated structure through a first adhesive layer and each electrically conducted with the first plating layer; the first circuit board and the second circuit board are each laminated to the first plating layer through a second adhesive layer to embed the electronic component.

5. The method of fabricating an embedded circuit board according to claim 1, wherein the electrodes of the electronic component are electrically connected to the first plating layer by a conductive paste printed between an inner surface of the slot and the electrodes of the electronic component.

6. An embedded circuit board, characterized in that, the embedded circuit board comprises at least an inner laminated structure, a first circuit board, a second circuit board, a third circuit board, a fourth circuit board, a first plating layer, and a second plating layer; the third circuit board and the fourth circuit board are respectively disposed on two sides of the inner laminated structure, and the embedded circuit board further comprises a slot; the slot penetrates the third circuit board, the inner laminated structure, and the fourth circuit board; the electronic component is received and fixed in the slot; electrodes of the electronic component are respectively directed to an inner surface of two ends of the slot; the first plating layer is disposed on an outer surface of the third circuit board and the fourth circuit board and a portion of an inner surface of the slot to electrically connect the third circuit board, the fourth circuit board, the inner laminated structure, and the electrodes of the electronic component; the first circuit board and the second circuit board are respectively disposed on an outer side of the first plating layer and cover an opening of the slot to embed the electronic component; the second plating layer is disposed on an outer side of the first circuit board and the second circuit board, and electrically connects the first circuit board and the second circuit board to the first plating layer.

7. The embedded circuit board according to claim 6, wherein two ends of the slot are semi-circular, and a middle of the slot has a rectangular shape; the first plating layer is partially disposed on an inner surface of the slot near the two ends; a conductive paste is disposed between the inner surface of the slot near the two ends and the electrodes of the electronic component to electrically connect the electrodes of the electronic component and the first plating layer.

8. The embedded circuit board according to claim 6, wherein the inner laminated structure comprises a flexible copper clad laminate, and a fifth circuit board and a sixth circuit board respectively disposed on two sides of the flexible copper clad laminate; the fifth circuit board and the sixth circuit board are each electrically connected to the first plating layer, and the fifth circuit board and the sixth circuit board each comprise a copper foil layer, an adhering layer, and a base film; the copper foil layer is attached to one side of the base film through the adhering layer, and the copper foil is laminated to the flexible copper clad laminate.

9. The embedded circuit board according to claim 6, wherein the inner laminated structure comprises a flexible copper clad laminate, a fifth circuit board and a sixth circuit board respectively disposed on two sides of the flexible copper clad laminate, and a seventh circuit board and an eighth circuit board respectively disposed on an outer side of the fifth circuit board and the sixth circuit board; the seventh circuit board and the eighth circuit board are respectively adhered to the fifth circuit board and the sixth circuit board through the adhering layer; the inner laminated structure further comprises an electrical conductor for realizing electrical conduction between the circuit boards of the respective layers, each circuit board layer of the inner laminated structure forms a filling hole; and the electric conductor fills in the filling hole to electrically conduct the respective circuit boards.

10. The embedded circuit board according to claim 6, wherein the third circuit board and the fourth circuit board are respectively laminated to two sides of the inner laminated structure through a first adhesive, and respectively electrically conducted with the first plating layer; the first circuit board and the second circuit board are each laminated to the first plating layer by a second adhesive layer to embed the electronic component.

11. The embedded circuit board according to claim 10, wherein the first circuit board and said second circuit board are further provided with a via respectively; the through holes penetrate the first circuit board/the second circuit board and the second adhesive layer; the second plating layer further comprises a conductive structure, the conductive structure filling the vias to electrically couple the first circuit board, the second circuit board, and the second plating layer to the first plating layer.
